(19) United States
(12) Patent Application Publication
(10) Pub. No.: US 2025/0017080 A1
(43) Pub. Date: Jan. 9, 2025

(54) ELECTRONIC DEVICE INCLUDING A SPACE DEFINED WITHIN AN ENCAPSULATION LAYER

(71) Applicant: SAMSUNG DISPLAY CO., LTD., YONGIN-SI (KR)

(72) Inventors: WOO YONG SUNG, YONGIN-SI (KR); SEUNGYONG SONG, YONGIN-SI (KR); HEE JUN YANG, YONGIN-SI (KR); JEONGSEOK LEE, YONGIN-SI (KR)

(21) Appl. No.: 18/616,093

(22) Filed: Mar. 25, 2024

(30) Foreign Application Priority Data
Jul. 3, 2023 (KR) 10-2023-0085963

(51) Int. Cl. H10K 59/80; H10K 59/122

(52) U.S. Cl. CPC H10K 59/873; H10K 59/122

(57) ABSTRACT

An electronic device includes a base layer. A circuit layer is disposed on the base layer. A light emitting element layer is disposed on the circuit layer and includes a light emitting element. An encapsulation layer includes a first encapsulation layer that covers the light emitting element layer, a second encapsulation layer disposed on the first encapsulation layer and including a space, a mask pattern layer disposed on the second encapsulation layer and including an opening, and a third encapsulation layer disposed on the second encapsulation layer and covering the mask pattern layer. A sensor layer is disposed on the encapsulation layer. The opening overlaps the space in a plan view.

### CROSS-REFERENCE TO RELATED APPLICATIONS

This application claims priority under 35 U.S.C. § 119 to Korean Patent Application No. 10-2023-0085963, filed on Jul. 3, 2023, in the Korean Intellectual Property Office, the disclosure of which is herein incorporated by reference in its entirety.

### TECHNICAL FIELD

The present disclosure relates to an electronic device and, more specifically, to an electronic device including a space defined within an encapsulation layer.

### DISCUSSION OF THE RELATED ART

Multimedia electronic devices such as a television (TV), a mobile phone, a tablet computer, a navigation system, and a portable game console include electronic devices for displaying images. Such electronic devices may include, in addition to a conventional input means such as a button, a keyboard, and a mouse, an input sensor capable of providing a touch-based input that allows a user to input information or commands easily and intuitively.

### SUMMARY

An electronic device includes a base layer. A circuit layer is disposed on the base layer. A light emitting element layer is disposed on the circuit layer and includes a light emitting element, an encapsulation layer including a first encapsulation layer that covers the light emitting element layer, a second encapsulation layer disposed on the first encapsulation layer and including a space defined therein, a mask pattern layer disposed on the second encapsulation layer and including an opening, and a third encapsulation layer disposed on the second encapsulation layer and covering the mask pattern layer. A sensor layer is disposed on the encapsulation layer. The opening overlaps the space in a plan view.

A width of the opening may be smaller than a width of the space.

A light emitting area may be defined in the light emitting element, and the mask pattern layer may overlap the light emitting area in a plan view.

A light emitting area may be defined in the light emitting element, and a light emitting opening overlapping the light emitting area, in a plan view, may be defined in the mask pattern layer.

The mask pattern layer may include a metal, a metal oxide, and/or an inorganic material.

The mask pattern layer may include a first pattern layer having a first material and a second pattern layer having a second material different from the first material.

The space may be sealed by the second encapsulation layer and the third encapsulation layer.

At least a portion of the third encapsulation layer may be accommodated within the space.

A bottom surface of the space may be defined by a portion of the second encapsulation layer, and the bottom surface of the space may be spaced apart from an upper surface of the first encapsulation layer.

A bottom surface of the space may be defined by a portion of the first encapsulation layer, and the bottom surface of the space may be a portion of an upper surface of the first encapsulation layer.

A portion of the third encapsulation layer may correspond to the space, and the third encapsulation layer may be in contact with the portion of the upper surface of the first encapsulation layer.

The light emitting element may include a first electrode disposed on the circuit layer, a light emitting layer disposed on the first electrode, and a second electrode disposed on the light emitting layer. The light emitting element layer may further include a pixel defining layer including a light emitting opening overlapping the first electrode and a partition wall disposed on the pixel defining layer and including a partition wall opening overlapping the light emitting opening. The second electrode may be in contact with the partition wall, and the space may overlap the partition wall in a plan view.

An electronic device includes a base layer. A circuit layer is disposed on the base layer. A light emitting element layer is disposed on the circuit layer and the light emitting element layer includes a plurality of light emitting areas. An encapsulation layer covers the light emitting element layer and includes a plurality of spaces at a portion of the encapsulation layer that does not overlap the plurality of light emitting areas. A sensor layer is disposed on the encapsulation layer. Each of the plurality of spaces is sealed by the encapsulation layer.

The encapsulation layer may include a first encapsulation layer that covers the light emitting element layer, a second encapsulation layer disposed on the first encapsulation layer and including the plurality of spaces, and a third encapsulation layer disposed on the second encapsulation layer.

The encapsulation layer may further include a mask pattern layer disposed on the second encapsulation layer and including a plurality of openings corresponding to the plurality of spaces on a one-to-one basis. Widths of the plurality of openings may be smaller than widths of the plurality of spaces.

A side surface and a bottom surface of each of the plurality of spaces may be defined by the second encapsulation layer, and the third encapsulation layer may cover each of the plurality of spaces.

A side surface and a bottom surface of each of the plurality of spaces may be defined by the second encapsulation layer, and a portion of the third encapsulation layer may be accommodated within a portion of each of the plurality of spaces.

A side surface of each of the plurality of spaces may be defined by the second encapsulation layer, and a bottom surface of each of the plurality of spaces may be defined by the first encapsulation layer.

A portion of the third encapsulation layer may be accommodated within each of the plurality of spaces and may be in contact with the side surface and the bottom surface of each of the plurality of spaces. The third encapsulation layer may be in contact with the first encapsulation layer.

The light emitting element layer may include a light emitting element including a first electrode disposed on the circuit layer, a light emitting layer disposed on the first electrode, and a second electrode disposed on the light emitting layer. A pixel defining layer may include a light emitting opening overlapping the first electrode. A partition wall may be disposed on the pixel defining layer. The partition wall may include a partition wall opening overlapping the light emitting opening. and the partition wall may be in contact with the second electrode. Each of the plurality of spaces may overlap the partition wall in a plan view.

### BRIEF DESCRIPTION OF THE DRAWINGS

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is a perspective view of an electronic device according to an embodiment of the present disclosure.

FIG. 3 is a cross-sectional view of an electronic device according to an embodiment of the present disclosure.

FIG. 4 is a cross-sectional view of an electronic device according to an embodiment of the present disclosure.

FIG. 5A is a cross-sectional view of an electronic device according to an embodiment of the present disclosure.

FIG. 5B is a plan view of an electronic device according to an embodiment of the present disclosure.

FIG. 6 is a cross-sectional view of an electronic device according to an embodiment of the present disclosure.

FIG. 7 is a cross-sectional view of an electronic device according to an embodiment of the present disclosure.

FIG. 8 is a cross-sectional view of an electronic device according to an embodiment of the present disclosure.

FIG. 9 is a cross-sectional view of an electronic device according to an embodiment of the present disclosure.

FIG. 10A is a cross-sectional view of an electronic device according to an embodiment of the present disclosure.

FIG. 10B is a plan view of an electronic device according to an embodiment of the present disclosure.

FIGS. 11A to 11D are cross-sectional views illustrating a method of manufacturing a display layer according to an embodiment of the present disclosure.

### DETAILED DESCRIPTION

In the present specification, the expression that a first component (or area, layer, part, portion, etc.) is “on”, “connected with”, or “coupled to” a second component may mean that the first component is directly on, connected with, or coupled to the second component or may mean that a third component is interposed therebetween.

The same reference numerals may refer to the same components throughout the specification and the figures. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The expression “and/or” includes one or more combinations which associated components are capable of defining.

Although the terms “first”, “second”, etc. may be used to describe various components, the components should not necessarily be limited by the terms. The terms are used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not necessarily exclude the presence or additional possibility of one or more other features, numbers, steps, operations, elements, or components or a combination thereof.

Hereinafter, an embodiment of the present disclosure will be described with reference to accompanying drawings.

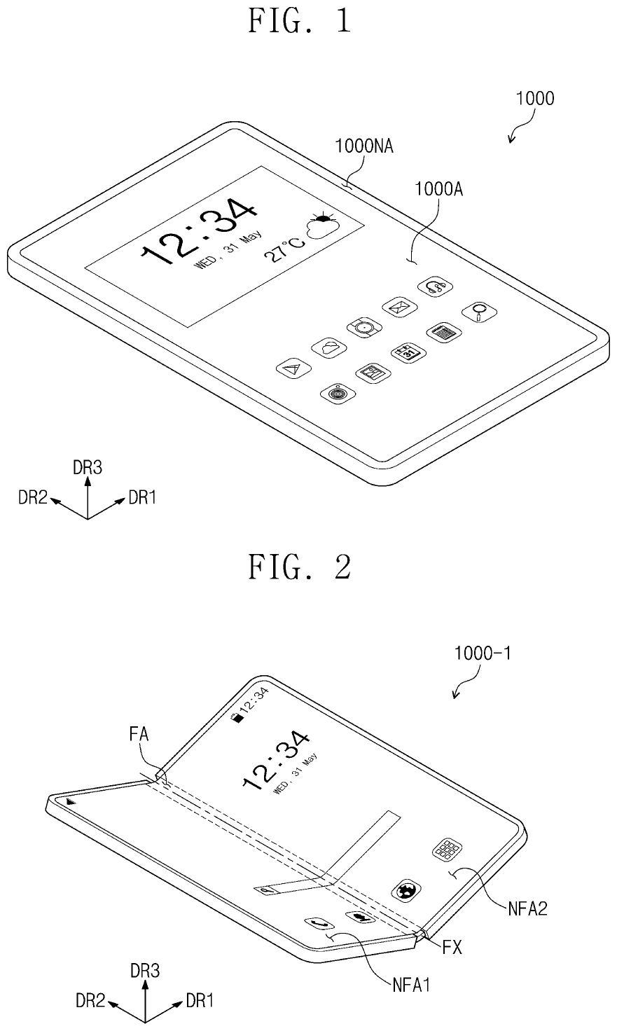

FIG. 1 is a perspective view of an electronic device 1000 according to an embodiment of the present disclosure.

Referring to FIG. 1, the electronic device 1000 may be a device that is activated according to an electric signal. For example, the electronic device 1000 may be a mobile phone, a portable mobile phone, a laptop computer, a television, a tablet computer, a vehicle navigation system, a portable game console, or a wearable device, but the present disclosure is not necessarily limited thereto. The wearable device, which is a device worn on a body of a user, may include a head mounted display HMD that implements eXtended reality XR. FIG. 1 exemplarily illustrates that the electronic device 1000 is a mobile phone (e.g., smartphone).

An active area 1000A and a peripheral area 1000NA may be defined in the electronic device 1000. The electronic device 1000 may display an image through the active area 1000A. The active area 1000A may include a plane defined by a first direction DR1 and a second direction DR2. The peripheral area 1000NA may at least partially surround a periphery of the active area 1000A. In an embodiment of the present disclosure, the peripheral area 1000NA may be omitted.

A thickness direction of the electronic device 1000 may be to the same as a third direction DR3 intersecting the first direction DR1 and the second direction DR2. Thus, front surfaces (or upper surfaces) and rear surfaces (or lower surfaces) of members constituting the electronic device 1000 may be defined based on the third direction DR3.

FIG. 2 is a perspective view of an electronic device 1000-1 according to an embodiment of the present disclosure.

Referring to FIG. 2, the electronic device 1000-1 may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA may refer to a foldable area, and the first and second non-folding areas NFA1 and NFA2 may refer to first and second non-foldable areas.

As illustrated in FIG. 2, the folding area FA may be folded with respect to a folding axis FX parallel to the second direction DR2. In a state in which the electronic device 1000-1 is folded, the folding area FA has a predetermined curvature and a predetermined radius of curvature. The first non-folding area NFA1 and the second non-folding area NFA2 may face each other, and the electronic device 1000-1 may be in-folded so that a display surface DS is not exposed to the outside when in the folded state.

In an embodiment of the present disclosure, the electronic device 1000-1 may be out-folded so that the display surface DS is exposed to the outside. In an embodiment of the present disclosure, the electronic device 1000-1 may be in-folded or out-folded in a state in which the electronic device 1000-1 is unfolded, but the present disclosure is not necessarily limited thereto.

FIG. 2 exemplarily illustrates that one folding axis FX is defined in the electronic device 1000-1, but the present disclosure is not necessarily limited thereto. For example, a plurality of folding axes may be defined in the electronic device 1000-1, and the electronic device 1000-1 may be in-folded or out-folded in an unfolded state on each of the plurality of folding axes.

FIGS. 1 and 2 exemplarily illustrate the bar type electronic device 1000 and the foldable type electronic device 1000-1, but the present disclosure is not necessarily limited thereto. For example, the following descriptions may be applied to various electronic devices such as a curved electronic device, a rollable electronic device, or a slidable electronic device.

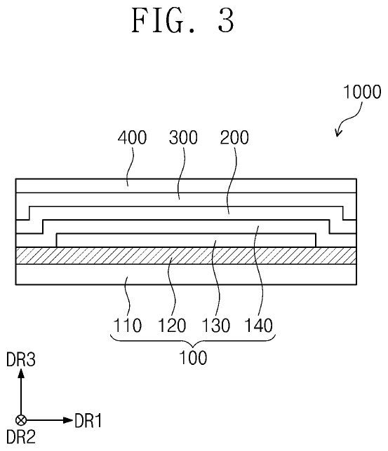

FIG. 3 is a cross-sectional view of the electronic device 1000 according to an embodiment of the present disclosure.

Referring to FIG. 3, the electronic device 1000 may include a display layer 100, a sensor layer 200, a reflection preventing layer 300, and a window 400. However, this is merely an example, and the electronic device 1000 might not include the reflection preventing layer 300 and the window 400.

The display layer 100 may include a base layer 110, a circuit layer 120, a light emitting element layer 130, and an encapsulation layer 140.

The base layer 110 may provide a base surface on which the circuit layer 120 is disposed. The base layer 110 may be a glass substrate, a metal substrate, a silicon substrate, a polymer substrate, or the like. However, an embodiment is not necessarily limited thereto, and the base layer 110 may be an inorganic layer, an organic layer, or a composite material layer.

The circuit layer 120 may be disposed on the base layer 110. The circuit layer 120 may include an insulation layer, a semiconductor pattern, a conductive pattern, a signal line, and the like. An insulating layer, a semiconductor layer, and a conductive layer are formed on the base layer 110 in a manner such as coating and deposition, and thereafter, the insulating layer, the semiconductor layer, and the conductive layer may be selectively patterned through a plurality of photolithography processes. Thereafter, the semiconductor pattern, the conductive pattern, and the signal line included in the circuit layer 120 may be formed.

The light emitting element layer 130 may be disposed on the circuit layer 120. The light emitting element layer 130 may include a light emitting element. For example, the light emitting element layer 130 may include an organic light emitting material, an inorganic light emitting material, an organic-inorganic light emitting material, a quantum dot, a quantum rod, a micro-light emitting diode (LED), or a nano-LED.

The encapsulation layer 140 may be disposed on the light emitting element layer 130. The encapsulation layer 140 may protect the light emitting element layer 130 from foreign substances such as moisture, oxygen, and dust particles.

The sensor layer 200 may be disposed on the display layer 100. The sensor layer 200 may be formed on the display layer 100 through a single continuous process. In this case, it may be expressed that the sensor layer 200 is directly disposed on the display layer 100. The aspect that the sensor layer 200 is directly disposed on the display layer 100 may mean that a third component is not disposed between the sensor layer 200 and the display layer 100. For example, a separate adhesive might not be disposed between the sensor layer 200 and the display layer 100. Alternatively, the sensor layer 200 may be coupled to the display layer 100 through an adhesive. The adhesive may include a general adhesive or a pressure-sensitive adhesive.

The reflection preventing layer 300 may be disposed on the sensor layer 200. The reflection preventing layer 300 may reduce reflectance of external light provided from outside of the electronic device 1000. The reflection preventing layer 300 may be directly disposed on the sensor layer 200. However, the present disclosure is not necessarily limited thereto, and an adhesive may be disposed between the reflection preventing layer 300 and the sensor layer 200.

The window 400 may be disposed on the reflection preventing layer 300. An adhesive may be disposed between the reflection preventing layer 300 and the window 400, but the present disclosure is not necessarily particularly limited thereto. The window 400 may include an optically transparent insulating material. For example, the window 400 may include a glass or a plastic. The window 400 may have a multi-layer structure or a single-layer structure. For example, the window 400 may include a plurality of plastic films coupled through an adhesive or include a glass substrate and a plastic substrate coupled through an adhesive.

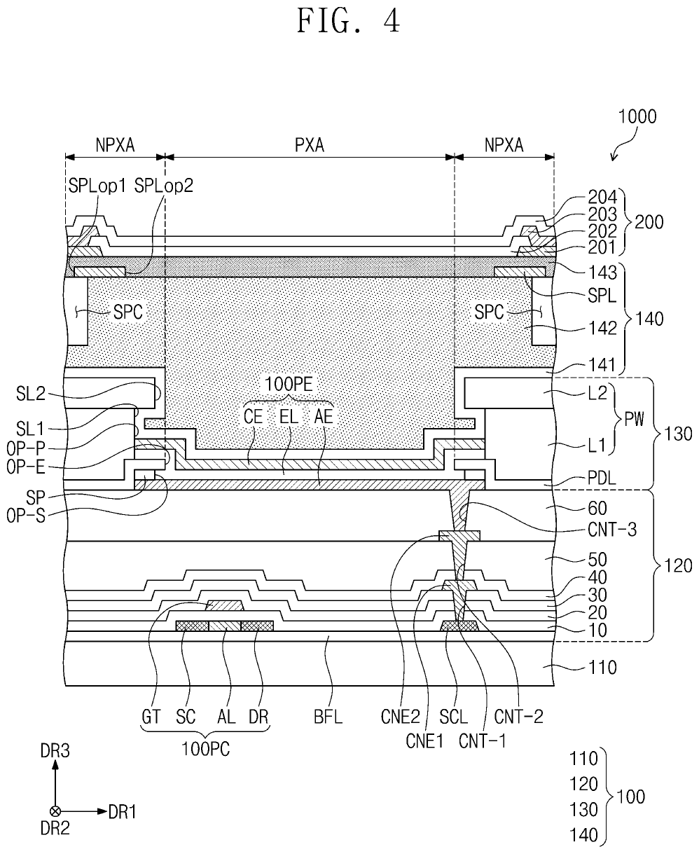

FIG. 4 is a cross-sectional view of the electronic device 1000 according to an embodiment of the present disclosure. FIG. 4 is a cross-sectional view of the display layer 100 and the sensor layer 200 among components of the electronic device 1000.

Referring to FIG. 4, at least one inorganic layer is formed on an upper surface of the base layer 110. The inorganic layer may include aluminum oxide, titanium oxide, silicon oxide, silicon nitride, silicon oxy nitride, zirconium oxide, and/or hafnium oxide. The inorganic layer may be formed in multiple layers. The multi-layered inorganic layers may constitute a barrier layer and/or a buffer layer. In an embodiment, the display layer 100 is illustrated as including a buffer layer BFL.

The buffer layer BFL may increase a bonding force between the base layer 110 and the semiconductor pattern. The buffer layer BFL may include silicon oxide, silicon nitride, and/or silicon oxy nitride. For example, the buffer layer BFL may include a structure in which silicon oxide layers and silicon nitride layers are alternately laminated.

The semiconductor pattern may be disposed on the buffer layer BFL. The semiconductor pattern may include poly silicon. However, the present disclosure is not necessarily limited thereto, and the semiconductor pattern may include amorphous silicon, low-temperature polycrystalline silicon, and/or an oxide semiconductor.

FIG. 4 merely illustrates a portion of the semiconductor pattern, and the semiconductor pattern may be further disposed in another area. The semiconductor pattern may be disposed in a specific manner across the pixels. The semiconductor pattern may have a different electrical property depending on whether or not the semiconductor pattern is doped. The semiconductor pattern may include a first area having higher conductivity and a second area having lower conductivity. The first area may be doped with an N-type dopant or a P-type dopant. A P-type transistor may include a doping area doped with the P-type dopant, and an N-type transistor may include a doping area doped with the N-type dopant. The second area may be a non-doping area or may be an area doped at a concentration lower than a concentration of doping of the first area.

A conductivity of the first area is greater than a conductivity of the second area, and the first area may substantially serve as an electrode or a signal line. The second area may substantially correspond to an active area (or a channel) of a transistor. For example, a portion of the semiconductor pattern may be an active area of the transistor, another portion of the semiconductor pattern may be a source area or a drain area of the transistor, and still another portion of the semiconductor pattern may be a connection electrode or a connection signal line.

Each of pixels may have an equivalent circuit including seven transistors, one capacitor, and a light emitting element, and the equivalent circuit of the pixel may be modified into various forms. FIG. 4 exemplarily illustrates one transistor 100PC and one light emitting element 100PE included in the pixel.

A source area SC, an active area AL, and a drain area DR of the transistor 100PC may be formed from the semiconductor pattern. The source area SC and the drain area DR may extend from the active area AL in opposite directions in a cross-sectional view. FIG. 4 illustrates a portion of a connection signal line SCL formed from the semiconductor pattern. Although not separately illustrated, the connection signal line SCL may be connected to the drain area DR of the transistor 100PC in a plan view.

In an embodiment of the present disclosure, the base layer 110 may be a silicon wafer substrate. In this case, a portion of the transistor 100PC may be mounted on or included in the base layer 110. For example, the source area SC, the active area AL, and the drain area DR may be included in the base layer 110.

A first insulating layer 10 may be disposed on the buffer layer BFL. The first insulating layer 10 may commonly overlap the plurality of pixels and may cover the semiconductor pattern. The first insulating layer 10 may be an inorganic layer and/or an organic layer and may have a single-layer structure or a multi-layer structure. The first insulating layer 10 may include aluminum oxide, titanium oxide, silicon oxide, silicon nitride, silicon oxy nitride, zirconium oxide, and/or hafnium oxide. In an embodiment, the first insulating layer 10 may be a single-layer silicon oxide layer. The first insulating layer 10 and an insulating layer of the circuit layer 120, which will be described below, may be an inorganic layer and/or an organic layer, and may have a single-layer structure or a multi-layer structure. The inorganic layer may include at least one of the above-described materials, but the present disclosure is not necessarily limited thereto.

A gate GT of the transistor 100PC is disposed on the first insulating layer 10. The gate GT may be a portion of a metal pattern. The gate GT overlaps the active area AL. The gate GT may function as a mask in a process of doping the semiconductor pattern.

A second insulating layer 20 may be disposed on the first insulating layer 10 and cover the gate GT. The second insulating layer 20 may commonly overlap the pixels. The second insulating layer 20 may be an inorganic layer and/or an organic layer and may have a single-layer structure or a multi-layer structure. The second insulating layer 20 may include silicon oxide, silicon nitride, and/or silicon oxy nitride. In an embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. For example, the third insulating layer 30 may have a multi-layer structure including a silicon oxide layer and a silicon nitride layer.

A first connection electrode CNE1 may be disposed on the third insulating layer 30. The first connection electrode CNE1 may be connected to the connection signal line SCL through a contact hole CNT-1 passing through the first insulating layer 10, the second insulating layer 20, and the third insulating layer 30.

A fourth insulating layer 40 may be disposed on the third insulating layer 30. The fourth insulating layer 40 may be a single-layer silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be disposed on the fifth insulating layer 50 and may cover the second connection electrode CNE2. The sixth insulating layer 60 may be an organic layer.

The light emitting element layer 130 may be disposed on the circuit layer 120. The light emitting element layer 130 may include the light emitting element 100PE, a sacrificial pattern SP, a pixel defining layer PDL, and a partition wall PW.

The light emitting element layer 130 may include an organic light emitting material, an inorganic light emitting material, an organic-inorganic light emitting material, a quantum dot, a quantum rod, a micro-LED, or a nano-LED. Hereinafter, it will be described that the light emitting element 100PE is an organic light emitting element, but the present disclosure is not necessarily particularly limited thereto.

The light emitting element 100PE may include a first electrode AE, a light emitting layer EL, and a second electrode CE. The first electrode AE may be referred to as an anode, and the second electrode CE may be referred to as a cathode.

The first electrode AE may be disposed on the sixth insulating layer 60. The first electrode AE may be connected to the second connection electrode CNE2 through a contact hole CNT-3 passing through the sixth insulating layer 60. Thus, the first electrode AE may be electrically connected to the connection signal line SCL through the first and second connection electrodes CNE1 and CNE2 and thus electrically connected to the corresponding circuit element. The first electrode AE may have a single-layer or multi-layer structure. The first electrode AE may include a plurality of layers including indium tin oxide (ITO) and silver (Ag). For example, the first electrode AE may include a layer including the ITO (hereinafter, referred to as a lower ITO layer), a layer disposed on the lower ITO layer and including Ag (hereinafter, referred to as an Ag layer), and a layer disposed on the Ag layer and including the ITO (hereinafter, referred to as an upper ITO layer).

The sacrificial pattern SP may be disposed between the first electrode AE and the pixel defining layer PDL. A sacrificial opening OP-S exposing a portion of an upper surface of the first electrode AE may be defined in the sacrificial pattern SP. The sacrificial opening OP-S may overlap a light emitting opening OP-E, which will be described below. The sacrificial pattern SP may include an amorphous transparent conductive oxide. The sacrificial pattern SP may include an azo compound. For example, the sacrificial pattern SP may be zinc oxide (ZnOₓ) doped with aluminum (Al). In this case, the content of the aluminum (Al) may be 2 at % or more and 5 at % or less.

The pixel defining layer PDL may be disposed on the sixth insulating layer 60 of the circuit layer 120. The light emitting opening OP-E may be defined by the pixel defining layer PDL. The light emitting opening OP-E may overlap the first electrode AE, and the pixel defining layer PDL may expose at least a portion of the first electrode AE through the light emitting opening OP-E.

Further, the light emitting opening OP-E may correspond to the sacrificial opening OP-S of the sacrificial pattern SP. According to an embodiment, the upper surface of the first electrode AE may be spaced apart from the pixel defining layer PDL on a cross section with the sacrificial pattern SP interposed therebetween, and accordingly, damage to the first electrode AE may be prevented in a process generated in the forming the light emitting opening OP-E.

An area of the light emitting opening OP-E may be smaller than an area of the sacrificial opening OP-S in a plan view. For example, an inner surface of the pixel defining layer PDL defining the light emitting opening OP-E may be closer to a center of the first electrode AE than an inner surface of the sacrificial pattern SP defining the sacrificial opening OP-S. However, this is illustrative, and the present disclosure is not necessarily limited thereto. For example, the inner surface of the sacrificial pattern SP may be substantially aligned with the inner surface of the pixel defining layer PDL. A light emitting area PXA may be considered as a partial area of the first electrode AE exposed from the sacrificial opening OP-S. FIG. 4 illustrates a peripheral area NPXA surrounding a periphery of the light emitting area PXA together. The peripheral area NPXA may overlap the partition wall PW, which will be described below.

The pixel defining layer PDL may include an inorganic insulating material. For example, the pixel defining layer PDL may include silicon nitride (SiNₓ). The pixel defining layer PDL may be disposed between the first electrode AE and the partition wall PW and block electrical connection between the first electrode AE and the partition wall PW.

The partition wall PW may be disposed on the pixel defining layer PDL. A partition wall opening OP-P may be defined in the partition wall PW. The partition wall opening OP-P may correspond to the light emitting opening OP-E and expose at least a portion of the first electrode AE.

The partition wall PW may have an undercut shape in a cross-sectional view. The partition wall PW may include a plurality of layers that are sequentially laminated, and at least one layer of the plurality of layers may be recessed as compared to other layers. Accordingly, the partition wall PW may include a tip portion.

The partition wall PW may include a first partition wall layer L1 and a second partition wall layer L2. The first partition wall layer L1 may be relatively recessed as compared to the second partition wall layer L2 with respect to the light emitting area PXA. For example, the first partition wall layer L1 may be undercut with respect to the second partition wall layer L2.

The partition wall opening OP-P defined in the partition wall PW may include a first area and a second area. The first partition wall layer L1 may include a first inner surface SL1 defining the first area of the partition wall opening OP-P, and the second partition wall layer L2 may include a second inner surface SL2 defining the second area. The first inner surface SL1 may be relatively inward recessed as compared to the second inner surface SL2. The second partition wall layer L2 protruding toward the light emitting area PXA may define a tip portion.

The first partition wall layer L1 may be disposed on the pixel defining layer PDL, and the second partition wall layer L2 may be disposed on the first partition wall layer L1. The first partition wall layer L1 may have a first conductivity and a first thickness, and the second partition wall layer L2 may have a second conductivity and a second thickness. The first conductivity may be greater than the second conductivity, and the first thickness may be greater than the second thickness.

FIG. 4 exemplarily illustrates that each of the first inner surface SL1 and the second inner surface SL2 is perpendicular to an upper surface of the pixel defining layer PDL, but the present disclosure is not necessarily limited thereto. For example, the partition wall PW may have a tapered shape or a reverse tapered shape.

The light emitting layer EL may be disposed on the first electrode AE. The light emitting layer EL may include a light emitting material. The light emitting element 100PE may further include a hole injection layer HIL and a hole transport layer HTL disposed between the light emitting layer EL and the first electrode AE and may further include an electron transport layer ETL and an electron injection layer EIL disposed between the light emitting layer EL and the second electrode CE.

The light emitting layer EL may be patterned by the tip portion defined by the partition wall PW. The light emitting layer EL may be disposed inside the sacrificial opening OP-S, the light emitting opening OP-E, and the partition wall opening OP-P. The light emitting layer EL may cover a portion of the upper surface of the pixel defining layer PDL exposed from the partition wall opening OP-P.

The second electrode CE may be disposed on the light emitting layer EL. The second electrode CE may be patterned by the tip portion defined by the partition wall PW. The second electrode CE may be in contact with the first inner surface SL1 of the first partition wall layer L1. The partition wall PW may include an electrically conductive material and receive a driving voltage, and accordingly, the second electrode CE may be electrically connected to the partition wall PW and receive the driving voltage.

FIG. 4 exemplarily illustrates that the light emitting layer EL and the second electrode CE are in contact with the first inner surface SL1 of the first partition wall layer L1, but the present disclosure is not necessarily limited thereto. For example, the light emitting layer EL might not be in contact with the first inner surface SL1 of the first partition wall layer L1.

According to an embodiment of the present disclosure, the display layer 100 may further include a capping pattern. The capping pattern may be disposed in the partition wall opening OP-P and may be disposed on the second electrode CE. The capping pattern may be patterned by the tip portion formed in the partition wall PW.

According to an embodiment of the present disclosure, the light emitting element 100PE may be formed without using a metal mask. Accordingly, damage due to contact with the metal mask may be prevented, the light emitting layer EL may be easily patterned even in the light emitting area PXA having a smaller size than that of an opening provided in the metal mask, and thus the display layer 100 having a high resolution may be provided. Further, according to an embodiment of the present disclosure, the light emitting element 100PE is physically separated from adjacent light emitting elements. Thus, current leakage or color mixing between the adjacent light emitting elements may be prevented.

The encapsulation layer 140 may be disposed on the light emitting element layer 130. The encapsulation layer 140 may include a first encapsulation layer 141, a second encapsulation layer 142, a mask pattern layer SPL, and a third encapsulation layer 143 that are sequentially laminated. The layers constituting the encapsulation layer 140 are not necessarily limited thereto. For example, the encapsulation layer 140 may further include an additional encapsulation layer in addition to the above-described component.

The first encapsulation layer 141 and the third encapsulation layer 143 may be inorganic layers. The first encapsulation layer 141 and the third encapsulation layer 143 may protect the light emitting element layer 130 from moisture and oxygen. The first encapsulation layer 141 and the third encapsulation layer 143 may include a silicon nitride layer, a silicon oxy nitride layer, a silicon oxide layer, a titanium oxide layer, an aluminum oxide layer, or the like.

The second encapsulation layer 142 may be an organic layer. The second encapsulation layer 142 may protect the light emitting element layer 130 from foreign substances such as dust particles. The second encapsulation layer 142 may cover the first encapsulation layer 141 and may provide a flat upper surface. In an embodiment of the present disclosure, the second encapsulation layer 142 may be a low-temperature organic material. For example, the second encapsulation layer 142 may be formed by slit coating or an inkjet process, and the second encapsulation layer 142 may provide a flattened upper surface.

According to an embodiment of the present disclosure, a predetermined space SPC may be defined in the second encapsulation layer 142. Air may be accommodated within the space SPC. The dielectric constant of the air may be 1.00059. Alternatively, the space SPC may be substantially evacuated. The dielectric constant of vacuum may be 1. Thus, the permittivity of the encapsulation layer 140 may be reduced by the space SPC defined in the second encapsulation layer 142. The space SPC may be referred to as a cavity.

According to an embodiment of the present disclosure, the space SPC is provided in the second encapsulation layer 142, and the permittivity of the encapsulation layer 140 is reduced. Thus, a selection range for selecting a material of the second encapsulation layer 142 may be widened. For example, even when the permittivity of the second encapsulation layer 142 is greater than or equal to three, the permittivity may be lowered by the space SPC, a material selection width of the second encapsulation layer 142 may increase. Thus, as a selection range of materials that may be applied to the second encapsulation layer 142 is widened, a range of refractive indexes that the second encapsulation layer 142 may also increase. For example, the refractive index of the second encapsulation layer 142 may be greater than or equal to 1.5.

The mask pattern layer SPL may be disposed on the second encapsulation layer 142. The mask pattern layer SPL may include a metal, a metal oxide, and/or an inorganic material. An opening SPLop1 corresponding to the space SPC may be defined in the mask pattern layer SPL. For example, the opening SPLop1 may overlap the space SPC in a plan view. In an embodiment of the present disclosure, a light emitting opening SPLop2 overlapping the light emitting area PXA may be further defined in the mask pattern layer SPL.

The third encapsulation layer 143 may be disposed on the second encapsulation layer 142 and may cover the mask pattern layer SPL. The opening SPLop1 of the mask pattern layer SPL may be completely blocked by the third encapsulation layer 143. Thus, the space SPC may have a completely sealed structure by the encapsulation layer 140.

In an embodiment of the present disclosure, the sensor layer 200 may be disposed on the encapsulation layer 140. The sensor layer 200 may include a first conductive layer 201, a sensing insulating layer 202, a second conductive layer 203, and a cover insulating layer 204. The sensing insulating layer 202 may be referred to as an intermediate insulating layer.

In an embodiment of the present disclosure, the sensor layer 200 may further include a base insulating layer disposed between the third encapsulation layer 143 and the first conductive layer 201. The base insulating layer may be an inorganic layer including silicon nitride, silicon oxy nitride, and/or silicon oxide. Alternatively, the base insulating layer may be an organic layer including an epoxy resin, an acrylic resin, or an imide-based resin. The base insulating layer may have a single-layer structure or may have a multi-layer structure in which layers are laminated in the third direction DR3.

Each of the first conductive layer 201 and the second conductive layer 203 may have a single-layer structure or have a multi-layer structure in which layers are laminated in the third direction DR3.

The conductive layer having a single-layer structure may include a metal layer or a transparent conductive layer. The metal layer may include molybdenum, silver, titanium, copper, aluminum, or alloys thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as poly(3,4-ethylenedioxythiophene) (PEDOT), a metal nanowire, graphene, or the like.

A conductive layer of a multi-layer structure may include metal layers. The metal layers may, for example, have a three-layer structure of titanium/aluminum/titanium. The conductive layer of the multi-layer structure may include at least one metal layer and at least one transparent conductive layer.

At least one of the sensing insulating layer 202 and the cover insulating layer 204 may include an inorganic film. The inorganic film may include aluminum oxide, titanium oxide, silicon oxide, silicon nitride, silicon oxy nitride, zirconium oxide, and/or hafnium oxide.

At least one of the sensing insulating layer 202 and the cover insulating layer 204 may include an organic film. The organic film may include an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and/or a perylene-based resin.

According to an embodiment of the present disclosure, the space SPC is defined in the encapsulation layer 140 and air is disposed in the space SPC or the space SPC is in a vacuum state. Thus, the permittivity of the encapsulation layer 140 disposed between the sensor layer 200 and the second electrode CE may be reduced by the space SPC. As the permittivity of the encapsulation layer 140 is reduced, noise generated due to coupling between the sensor layer 200 and the second electrode CE may be reduced. Thus, the electronic device 1000 having the sensor layer 200 having increased sensitivity by reducing a signal-to-noise ratio (SNR) may be provided.

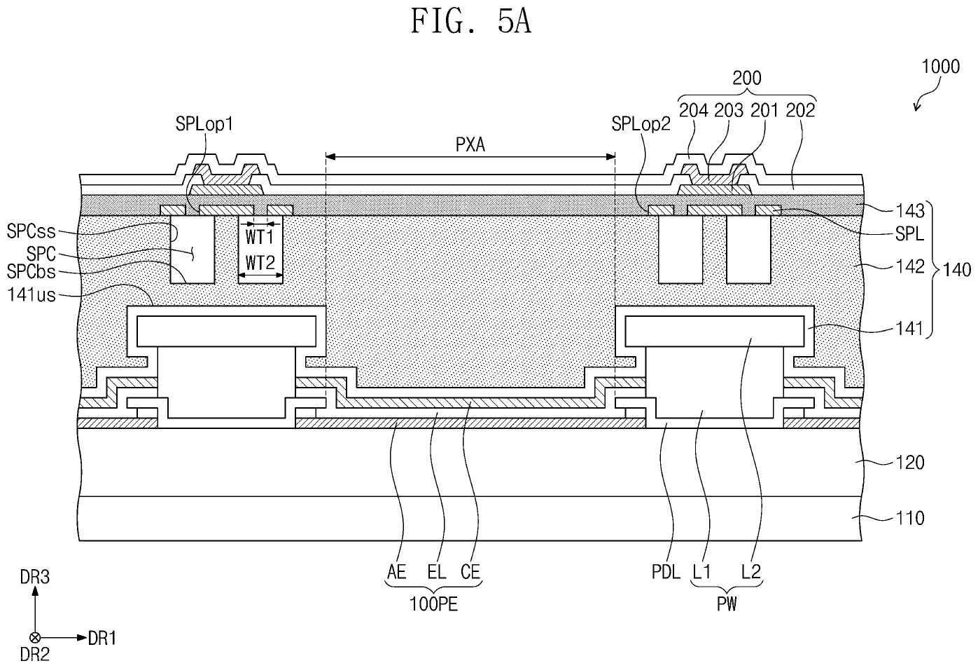

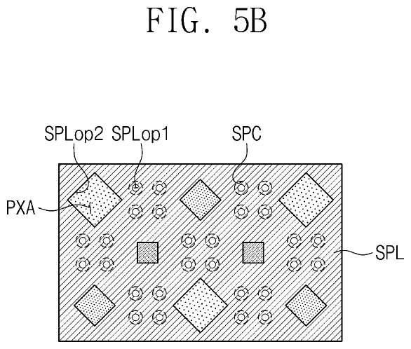

FIG. 5A is a cross-sectional view of the electronic device 1000 according to an embodiment of the present disclosure. FIG. 5B is a plan view of the electronic device according to an embodiment of the present disclosure.

Referring to FIGS. 5A and 5B, a plurality of spaces SPC may be defined in a portion of the encapsulation layer 140, which does not overlap the light emitting area PXA. Each of the plurality of spaces SPC may be completely sealed by the encapsulation layer 140.

A plurality of openings SPLop1 corresponding to the spaces SPC on a one-to-one basis may be defined in the mask pattern layer SPL. The third encapsulation layer 143 may be formed by a chemical vapor deposition method. In this process, the openings SPLop1 may be filled with a portion of the third encapsulation layer 143. A width WT1 of each of the opening SPLop1 may be less than several micrometers, for example, less than one micrometer, but the present disclosure is not necessarily limited thereto. For example, as long as the openings SPLop1 may be filled with the portion of the third encapsulation layer 143, the size of the width WT1 of each of the openings SPLop1 is not particularly limited thereto.

In an embodiment of the present disclosure, the width WT1 of each of the openings SPLop1 may be smaller than a width WT2 of each of the plurality of spaces SPC. Thus, a width WT2 of the spaces SPC for implementing a low refractive index is not necessarily limited to the width WT1 of each of the openings SPLop1 and may be designed in various manners.

In an embodiment of the present disclosure, a side surface SPCss and a bottom surface SPCbs of each of the spaces SPC may be defined by the second encapsulation layer 142. The bottom surface SPCbs of each of the spaces SPC may be spaced apart from an upper surface 141us of the first encapsulation layer 141. The third encapsulation layer 143 may cover each of the spaces SPC. For example, each of the spaces SPC may be sealed by the second encapsulation layer 142 and the third encapsulation layer 143.

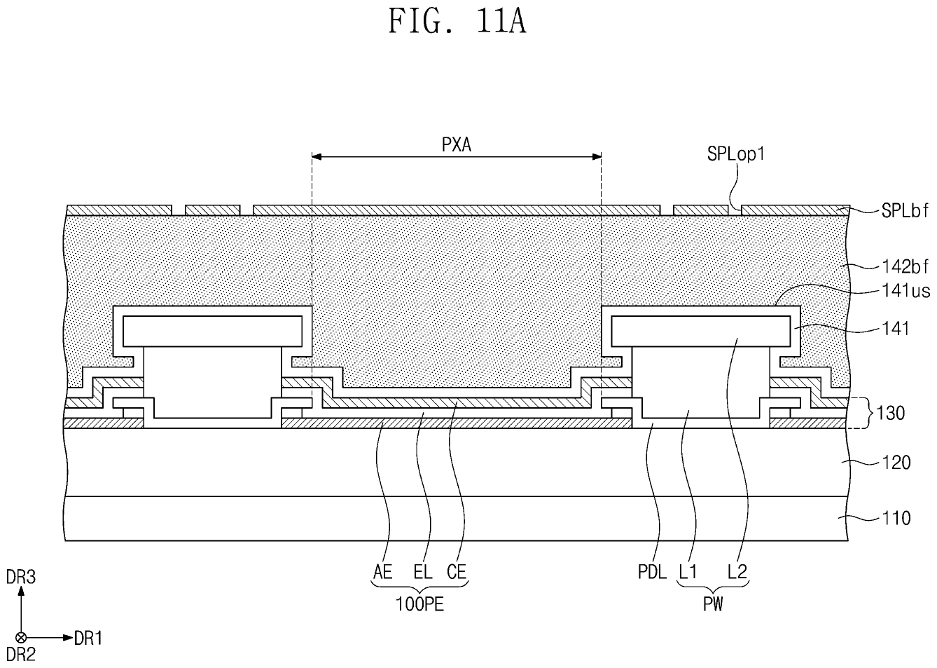

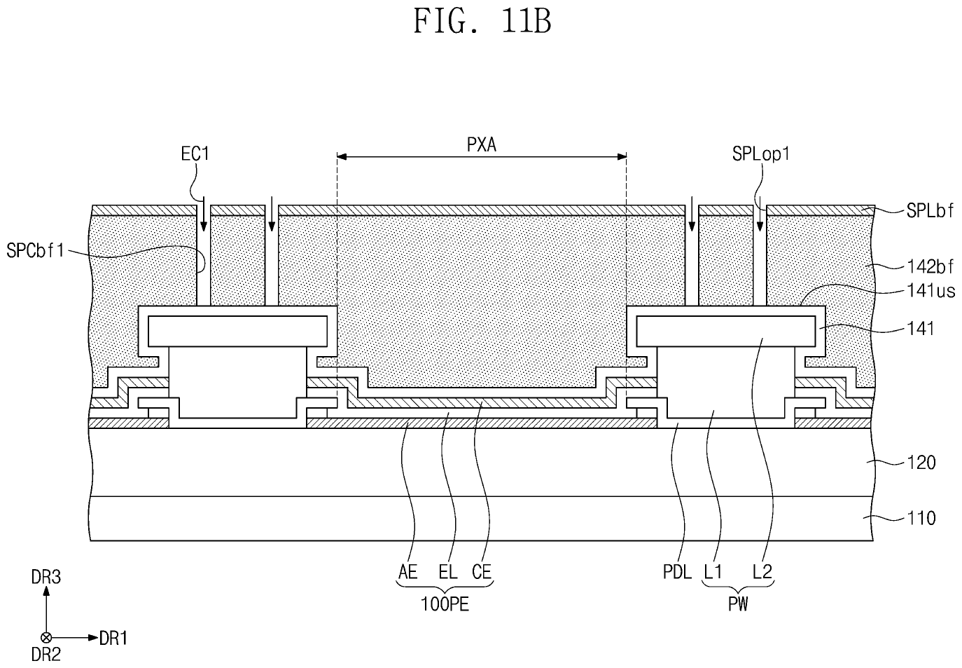

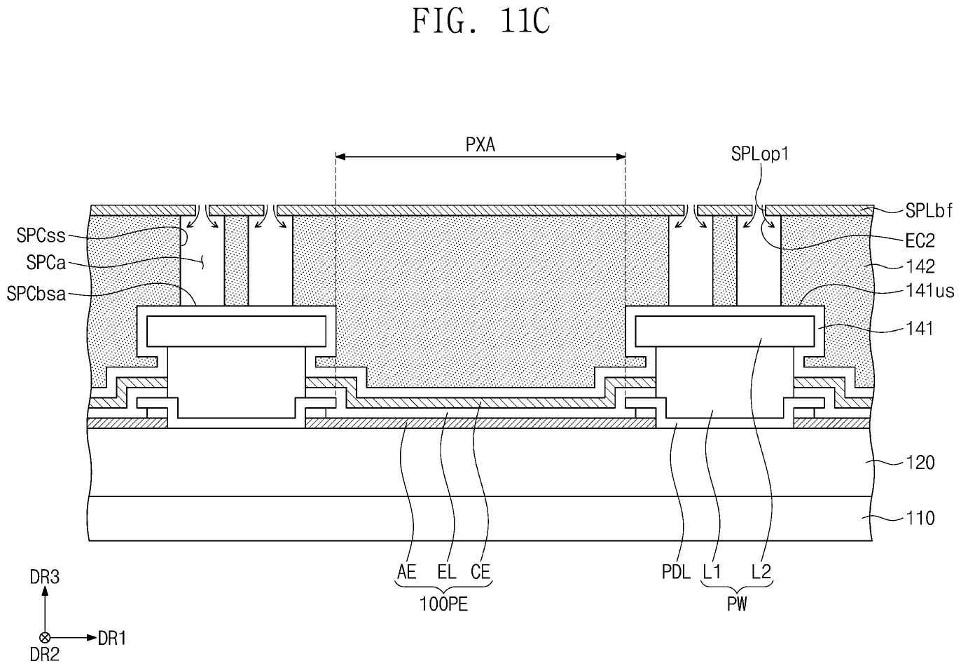

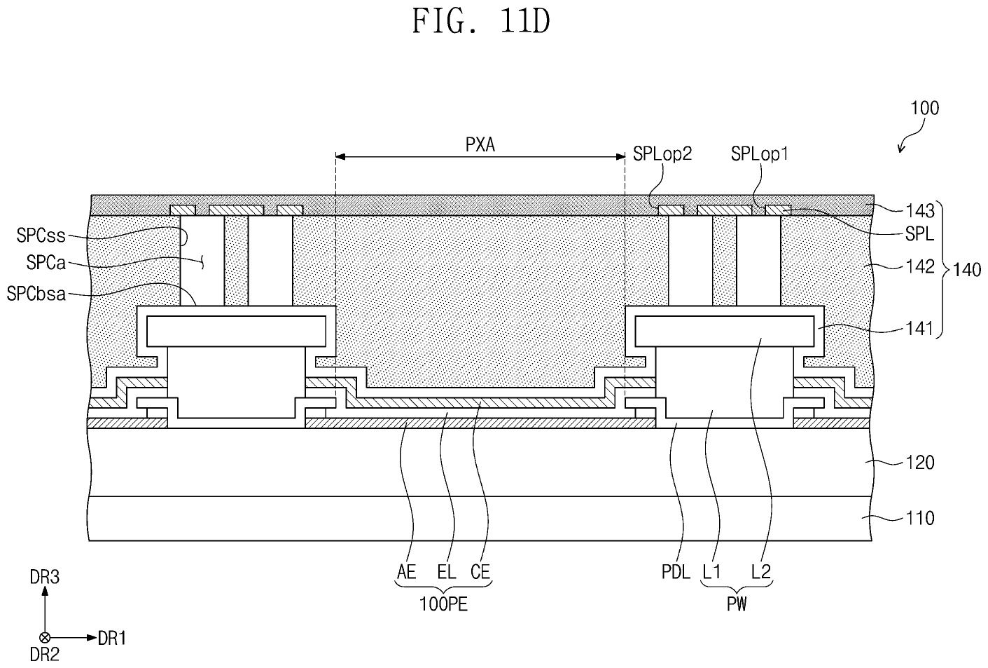

Referring to FIG. 5B, the mask pattern layer SPL is exemplarily illustrated. The opening SPLop1 overlapping the space SPC and the light emitting opening SPLop2 overlapping the light emitting area PXA may be defined in the mask pattern layer SPL. The opening SPLop1 defined in the mask pattern layer SPL may be smaller than the space SPC in a plan view. For example, the opening SPLop1 may have a size capable of being sealed by the third encapsulation layer 143 when the third encapsulation layer 143 (see FIG. 11D) is formed.

According to an embodiment of the present disclosure, the space SPC is defined by the encapsulation layer 140 and air is disposed in the space SPC or the space SPC is in a vacuum state. Thus, the permittivity of the encapsulation layer 140 disposed between the sensor layer 200 and the second electrode CE may be reduced by the space SPC. As the permittivity of the encapsulation layer 140 is reduced, noise generated due to coupling between the sensor layer 200 and the second electrode CE may be reduced. Thus, the electronic device 1000 having the sensor layer 200 having increased sensitivity by reducing the SNR may be provided.

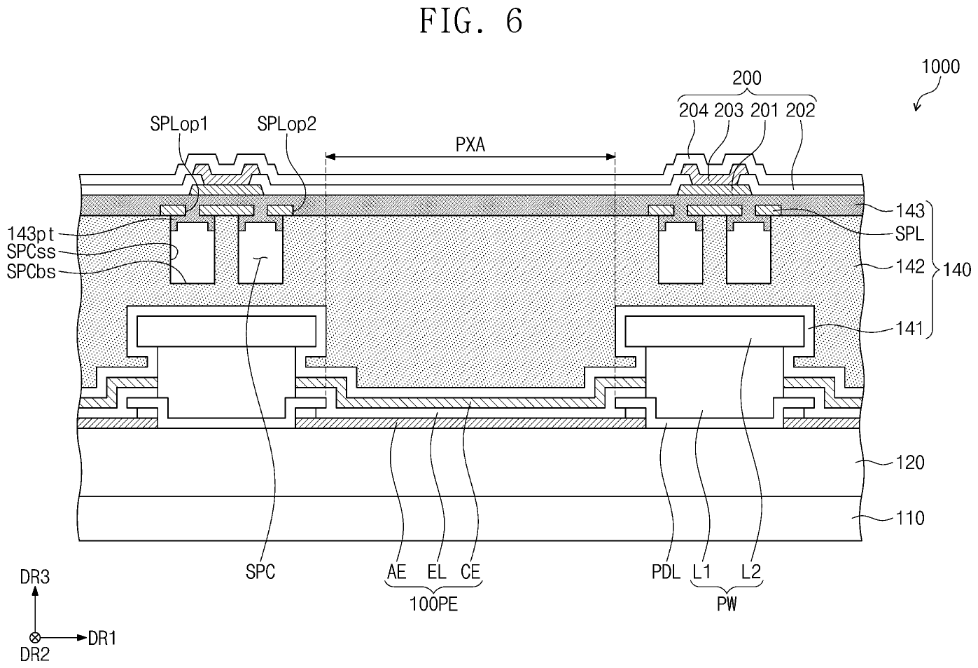

FIG. 6 is a cross-sectional view of the electronic device 1000 according to an embodiment of the present disclosure.

Referring to FIGS. 6, the plurality of spaces SPC may be defined in a portion of the encapsulation layer 140, which does not overlap the light emitting area PXA. Each of the of spaces SPC may be completely sealed by the encapsulation layer 140.

The plurality of openings SPLop1 corresponding to the spaces SPC on a one-to-one basis may be defined in the mask pattern layer SPL. The third encapsulation layer 143 may be formed by a chemical vapor deposition method. In this process, the openings SPLop1 may be filled with a portion of the third encapsulation layer 143. In an embodiment of the present disclosure, at least a portion 143pt of the third encapsulation layer 143 may be accommodated within the spaces SPC.

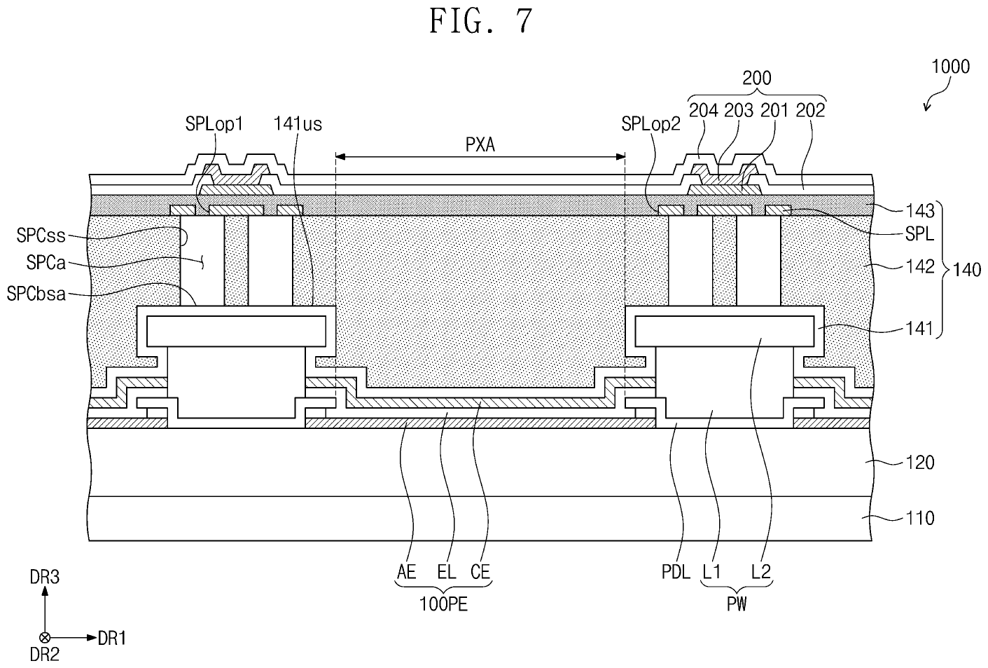

FIG. 7 is a cross-sectional view of the electronic device 1000 according to an embodiment of the present disclosure.

Referring to FIG. 7, a plurality of spaces SPCa may be defined in a portion of the encapsulation layer 140, which does not overlap the light emitting area PXA. Each of the of spaces SPCa may be completely sealed by the encapsulation layer 140.

In an embodiment of the present disclosure, a bottom surface SPCbsa of each of the plurality of spaces SPCa may be defined by a portion of the first encapsulation layer 141, and a side surface SPCss may be defined by the second encapsulation layer 142. The bottom surface SPCbsa of each of the spaces SPCa may be a portion of the upper surface 141us of the first encapsulation layer 141. The first encapsulation layer 141 may serve as an etch stopper during a process of forming the spaces SPCa. The third encapsulation layer 143 may cover each of the spaces SPCa. For example, each of the spaces SPCa may be sealed by the first encapsulation layer 141, the second encapsulation layer 142, and the third encapsulation layer 143.

According to an embodiment of the present disclosure, a height of the space SPCa may correspond to a thickness of the second encapsulation layer 142. For example, the space SPCa may have a through structure that passes through the second encapsulation layer 142. Thus, the volume of the space SPCa may be increased, and accordingly, the permittivity of the encapsulation layer 140 may be further reduced. As the permittivity of the encapsulation layer 140 is reduced, noise generated due to coupling between the sensor layer 200 and the second electrode CE may be reduced. Thus, the electronic device 1000 having the sensor layer 200 having increased sensitivity by reducing the SNR may be provided.

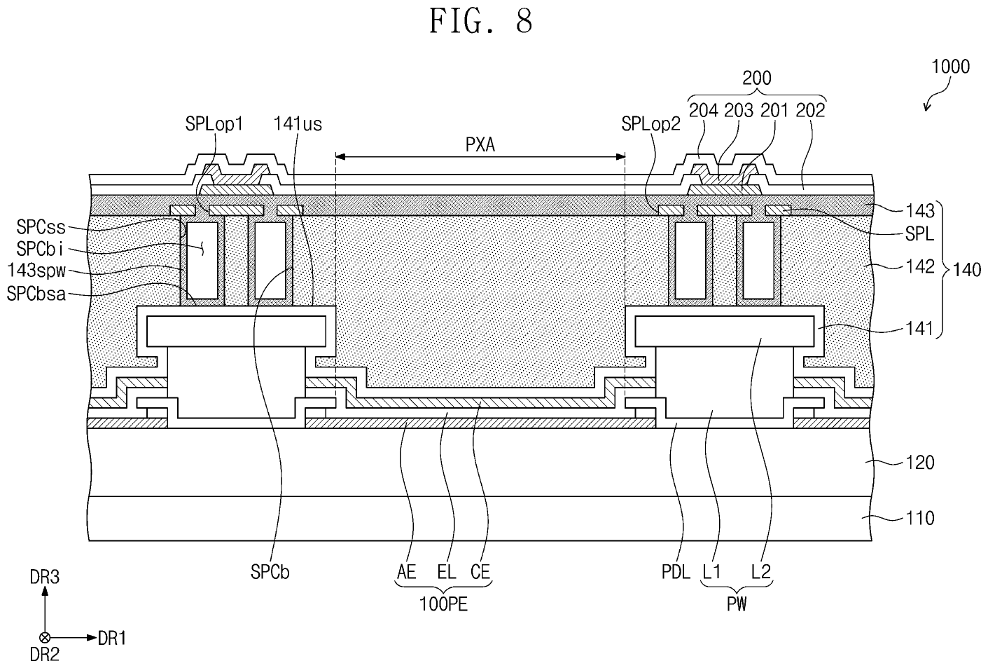

FIG. 8 is a cross-sectional view of the electronic device 1000 according to an embodiment of the present disclosure.

Referring to FIG. 8, a plurality of spaces SPCb may be defined in a portion of the encapsulation layer 140, which does not overlap the light emitting area PXA. Each of the of spaces SPCb may be completely sealed by the encapsulation layer 140. The plurality of openings SPLop1 corresponding to the spaces SPCb on a one-to-one basis may be defined in the mask pattern layer SPL. The third encapsulation layer 143 may be formed by a chemical vapor deposition method. In this process, the openings SPLop1 may be filled with a portion of the third encapsulation layer 143. In an embodiment of the present disclosure, at least a portion 143spw of the third encapsulation layer 143 may be disposed to correspond to the spaces SPCb.

In an embodiment of the present disclosure, the third encapsulation layer 143 may have a shape covering the bottom surface SPCbsa and the side surface SPCss of each of the spaces SPCb. Thus, spaces SPCbi having a smaller volume than that of the spaces SPCb may be defined by the third encapsulation layer 143. The third encapsulation layer 143 may be in contact with the bottom surface SPCbsa and the side surface SPCss of each of the spaces SPCb and in contact with the first encapsulation layer 141.

According to an embodiment of the present disclosure, since the first encapsulation layer 141 and the third encapsulation layer 143 are in contact with an in which where the spaces SPCb are defined, the effect of delaying moisture permeation may be maximized. Thus, an effect of protecting the light emitting element layer 130 by the encapsulation layer 140 may be increased.

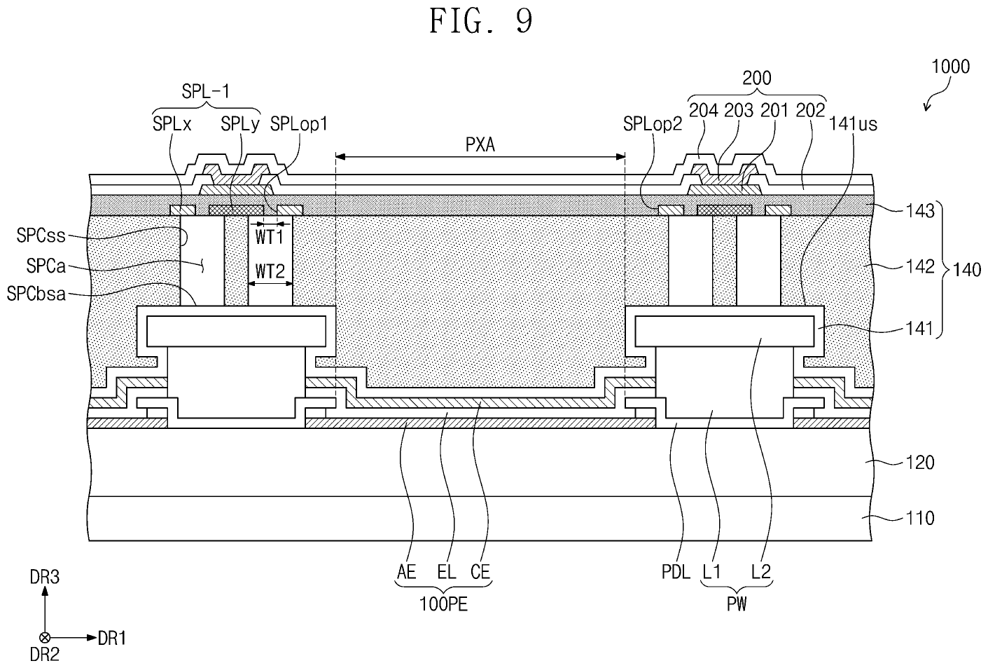

FIG. 9 is a cross-sectional view of the electronic device 1000 according to an embodiment of the present disclosure.

Referring to FIG. 9, the plurality of spaces SPCa may be defined in a portion of the encapsulation layer 140, which does not overlap the light emitting area PXA. Each of the of spaces SPCa may be completely sealed by the encapsulation layer 140. The plurality of openings SPLop1 corresponding to the plurality of spaces SPCa on a one-to-one basis may be defined in a mask pattern layer SPL-1. The third encapsulation layer 143 may be formed by a chemical vapor deposition method. In this process, the openings SPLop1 may be filled with a portion of the third encapsulation layer 143. The width WT1 of each of the opening SPLop1 may be less than one micrometer, but the present disclosure is not necessarily limited thereto. For example, as long as the openings SPLop1 may be filled with the portion of the third encapsulation layer 143, the size of the width WT1 of each of the openings SPLop1 is not particularly limited thereto.

In an embodiment of the present disclosure, the mask pattern layer SPL-1 may include a heterogeneous material to minimize the width WT1 of each of the openings SPLop1. For example, the mask pattern layer SPL-1 may include a first pattern layer SPLx having a first material and a second pattern layer SPLy having a second material different from the first material.

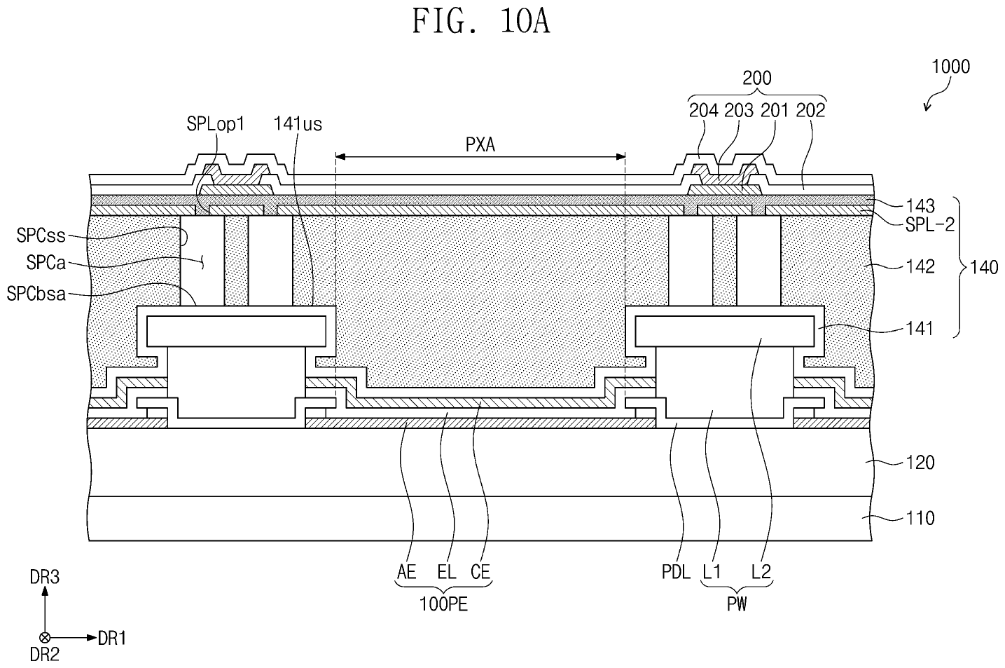

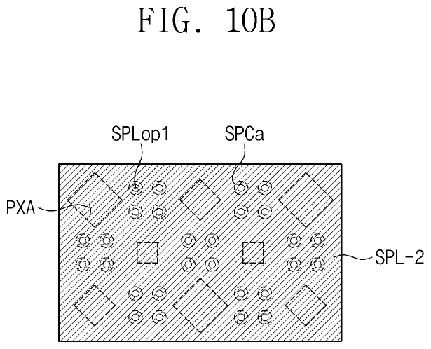

FIG. 10A is a cross-sectional view of the electronic device 1000 according to an embodiment of the present disclosure. FIG. 10B is a plan view of the electronic device 1000 according to an embodiment of the present disclosure.

Referring to FIGS. 10A and 10B, a mask pattern layer SPL-2 may be disposed on the second encapsulation layer 142. The opening SPLop1 overlapping the space SPC may be defined in the mask pattern layer SPL-2. The mask pattern layer SPL may include a metal, a metal oxide, and/or an inorganic material. In an embodiment of the present disclosure, the mask pattern layer SPL-2 may include a light-transmitting material. In this case, the mask pattern layer SPL-2 may overlap the light emitting area PXA.

The embodiments described above with reference to FIGS. 5A to 10B may be combined with each other within a mutually possible range. The space SPC, SPCa, or SPCb may be defined in the encapsulation layer 140 and air is disposed in the space SPC, SPCa, or SPCb or the space SPC, SPCa, or SPCb may be in a vacuum state. Thus, the permittivity of the encapsulation layer 140 disposed between the sensor layer 200 and the second electrode CE may be reduced by the space SPC, SPCa or SPCb. As the permittivity of the encapsulation layer 140 is reduced, noise generated due to coupling between the sensor layer 200 and the second electrode CE may be reduced. Thus, the electronic device 1000 having the sensor layer 200 having increased sensitivity by reducing the SNR may be provided.

FIGS. 11A to 11D are cross-sectional views illustrating some of operations of a method of manufacturing the display layer 100 according to an embodiment of the present disclosure.

Referring to FIG. 11A, the first encapsulation layer 141 is formed on the light emitting element layer 130. The first encapsulation layer 141 may be formed by a chemical vapor deposition method.

A second preliminary encapsulation layer 142bf is formed on the first encapsulation layer 141. The second preliminary encapsulation layer 142bf may include a low-temperature organic film. The second preliminary encapsulation layer 142bf may be formed by various processes. For example, the second preliminary encapsulation layer 142bf may be formed using a slit coating method or an inkjet coating method.

A mask pattern layer SPLbf is formed on the second preliminary encapsulation layer 142bf. The opening SPLop1 is defined in the mask pattern layer SPLbf. A portion of the second preliminary encapsulation layer 142bf may be exposed through the opening SPLop1. The mask pattern layer SPLbf may include a metal, a metal oxide, and/or an inorganic material.

The mask pattern layer SPLbf may be formed by a single process or a plurality of processes. For example, various processes may be utilized according to the size of the opening SPLop1 or process equipment. For example, when the mask pattern layer SPLbf is formed by a plurality of processes, the mask pattern layer SPLbf may include a plurality of pattern layers having different materials.

Referring to FIG. 11B, the second preliminary encapsulation layer 142bf is primarily etched (EC1). The primary etching EC1 may be dry etching or may be anisotropic etching having a specific directionality.

Referring to FIGS. 11B and 11C, the second preliminary encapsulation layer 142bf is secondarily etched (EC2). The secondary etching EC2 may be dry etching or may be isotropic etching. The space SPCa formed by the primary etching EC1 and the secondary etching EC2 may have an undercut shape with respect to the mask pattern layer SPLbf.

While the first etching EC1 and the second etching EC2 are performed, the mask pattern layer SPLbf may cover the light emitting area PXA. Thus, a portion of the second preliminary encapsulation layer 142bf, which overlaps the light emitting area PXA, might not be etched.

Referring to FIGS. 11C and 11D, the light emitting opening SPLop2 is formed in the mask pattern layer SPLbf. The light emitting opening SPLop2 may overlap the light emitting area PXA. As illustrated in FIG. 10A, when the mask pattern layer SPLbf includes a light-transmitting material, a process of forming the light emitting opening SPLop2 in the mask pattern layer SPLbf may be omitted.

Thereafter, the third encapsulation layer 143 may be formed by a chemical vapor deposition method. The opening SPLop1 defined in the mask pattern layer SPL may be blocked by the third encapsulation layer 143. Thus, the space SPCa may have a structure completely sealed by the encapsulation layer 140.

According to the above description, a space may be defined in an encapsulation layer and air may be disposed in the space or the space may be in a vacuum state. Thus, the permittivity of the encapsulation layer disposed between a sensor layer and a second electrode may be reduced by the space. As the permittivity of the encapsulation layer is reduced, noise generated due to coupling between the sensor layer and the second electrode may be reduced. Thus, an electronic device having the sensor layer having increased sensitivity by reducing a signal-to-noise ratio may be provided.

Although the description has been made above with reference to an embodiment of the present disclosure, it may be understood that those skilled in the art or those having ordinary knowledge in the art may variously modify and changes the present disclosure without departing from the spirit and technical scope of the present disclosure.

What is claimed is:

1. An electronic device, comprising:
a base layer;
a circuit layer disposed on the base layer;
a light emitting element layer disposed on the circuit layer, and the light emitting element layer including a light emitting element;
an encapsulation layer including:
a first encapsulation layer that covers the light emitting element layer,
a second encapsulation layer disposed on the first encapsulation layer, the second encapsulation layer including a space defined therein,
a mask pattern layer disposed on the second encapsulation layer, the mask pattern including an opening defined therein, and
a third encapsulation layer disposed on the second encapsulation layer, and the third encapsulation layer covering the mask pattern layer; and
a sensor layer disposed on the encapsulation layer,
wherein the opening overlaps the space in a plan view.

2. The electronic device of claim 1, wherein a width of the opening is smaller than a width of the space.

3. The electronic device of claim 1, wherein a light emitting area is defined in the light emitting element, and
wherein the mask pattern layer overlaps the light emitting area in a plan view.

4. The electronic device of claim 1, wherein a light emitting area is defined in the light emitting element, and
wherein a light emitting opening overlapping the light emitting area, in a plan view, is defined in the mask pattern layer.

5. The electronic device of claim 1, wherein the mask pattern layer includes a metal, a metal oxide, and/or an inorganic material.

6. The electronic device of claim 1, wherein the mask pattern layer includes a first pattern layer including a first material and a second pattern layer including a second material different from the first material.

7. The electronic device of claim 1, wherein the space is sealed by the second encapsulation layer and the third encapsulation layer.

8. The electronic device of claim 1, wherein at least a portion of the third encapsulation layer is accommodated within the space.

9. The electronic device of claim 1, wherein a bottom surface of the space is defined by a portion of the second encapsulation layer, and the bottom surface of the space is spaced apart from an upper surface of the first encapsulation layer.

10. The electronic device of claim 1, wherein a bottom surface of the space is defined by a portion of the first encapsulation layer, and the bottom surface of the space is a portion of an upper surface of the first encapsulation layer.

11. The electronic device of claim 10, wherein a portion of the third encapsulation layer corresponds to the space, and the third encapsulation layer is in contact with the portion of the upper surface of the first encapsulation layer.

12. The electronic device of claim 1, wherein the light emitting element includes a first electrode disposed on the circuit layer, a light emitting layer disposed on the first electrode, and a second electrode disposed on the light emitting layer,
wherein the light emitting element layer further includes a pixel defining layer including a light emitting opening overlaps the first electrode and a partition wall disposed on the pixel defining layer, a partition wall opening overlapping the light emitting opening,
wherein the second electrode is in contact with the partition wall, and
wherein the space overlaps the partition wall in a plan view.

13. An electronic device, comprising:
a base layer;
a circuit layer disposed on the base layer;
a light emitting element layer disposed on the circuit layer and including a plurality of light emitting areas;
an encapsulation layer covering the light emitting element layer and including a plurality of spaces at a portion of the encapsulation layer, that does not overlap the plurality of light emitting areas; and
a sensor layer disposed on the encapsulation layer,
wherein each of the plurality of spaces is sealed by the encapsulation layer.

14. The electronic device of claim 13, wherein the encapsulation layer includes:
a first encapsulation layer covering the light emitting element layer;
a second encapsulation layer disposed on the first encapsulation layer and including the plurality of spaces; and
a third encapsulation layer disposed on the second encapsulation layer.

15. The electronic device of claim 14, wherein the encapsulation layer further includes a mask pattern layer disposed on the second encapsulation layer and including a plurality of openings corresponding to the plurality of spaces on a one-to-one basis, and widths of the plurality of openings are smaller than widths of the plurality of spaces.

16. The electronic device of claim 14, wherein a side surface and a bottom surface of each of the plurality of spaces is defined by the second encapsulation layer, and the third encapsulation layer covers each of the plurality of spaces.

17. The electronic device of claim 14, wherein a side surface and a bottom surface of each of the plurality of spaces is defined by the second encapsulation layer, and a portion of the third encapsulation layer is accommodated within a portion of each of the plurality of spaces.

18. The electronic device of claim 14, wherein a side surface of each of the plurality of spaces is defined by the second encapsulation layer, and a bottom surface of each of the plurality of spaces is defined by the first encapsulation layer.

19. The electronic device of claim 18, wherein a portion of the third encapsulation layer is accommodated within each of the plurality of spaces and is in contact with the side surface and the bottom surface of each of the plurality of spaces, and the third encapsulation layer is in contact with the first encapsulation layer.

20. The electronic device of claim 13, wherein the light emitting element layer includes:
a light emitting element including a first electrode disposed on the circuit layer, a light emitting layer disposed on the first electrode, and a second electrode disposed on the light emitting layer;
a pixel defining layer including a light emitting opening overlapping the first electrode; and
a partition wall disposed on the pixel defining layer, the partition wall including a partition wall opening overlapping the light emitting opening, the partition wall is in contact with the second electrode, and
wherein each of the plurality of spaces overlaps the partition wall in a plan view.
